(19) United States
(12) Patent Application Publication
(10) Pub. No.: US 2008/0211598 A1
(43) Pub. Date: Sep. 4, 2008

(54) ON-CHIP IMPEDANCE MATCHING USING A VARIABLE CAPACITOR

(76) Inventor: Brian Keith Eplett, Lilburn, GA (US)

Correspondence Address: Fleit Gibbons Gutman Bongini & Bianco PL, 21355 EAST DIXIE HIGHWAY, SUITE 115, MIAMI, FL, 33180, US

(21) Appl. No.: 11/680,644

(22) Filed: Mar. 1, 2007

(51) Int. Cl. H03H 7/38

(52) U.S. Cl. 333/17.3

(57) ABSTRACT

A system and a method for on-chip impedance matching, of at least two ports: an output source and an input load. The system includes an on-chip integrated impedance matching circuit (IMC) that comprises: at least one variable capacitor; a control unit that enables tuning of the variable capacitor, receiving and transmitting of signals and processing of signals; and at least one peak detector that enables detection of signal peaks (SP). Control unit enables determining of a substantially optimal signal peak and tuning of the variable capacitor to a substantially optimal capacitance that is corresponding to the said optimal signal peak. The highest signal peak provides the substantially optimal impedance matching between the ports.

### FIELD OF THE INVENTION

The present invention generally relates to the field of electrical circuits for impedance matching, and more specifically, the present invention relates to on-chip impedance matching.

### BACKGROUND OF THE INVENTION

When connecting electronic components together to carry electromagnetic signals, it is important to match impedance, which can be achieved with various matching devices. Failing to do so is known as impedance mismatch and may result in signal loss and reflections. Impedance matching is the practice of attempting to make the output impedance of a source equal to the input impedance of a load to which it is ultimately connected, usually in order to maximize the power transfer and minimize reflections from the load. The input impedance or load impedance of a circuit or electronic devices is the impedance actually experienced by a signal which is connected to its input. On-chip impedance matching presents additional designing considerations, since the electric circuit and components need to fit into a much smaller board space and since submicron (nano) processes present more process variations that affect the performances of the chip processes.

U.S. Pat. No. 6,414,562, by Bouisse Gerard Jean Louis discloses a circuit and a method for impedance matching of a load to a radio frequency (RF) amplifier. Louis's circuit includes a control logic circuit that adjusts the capacitance and inductance values of variable capacitance and inductance to adjust an impedance match. Louis uses both variable inductance and variable capacitance and compares the transmitted signal and the reflected signal and calculates the impedance mismatch. Louis's system then sets both capacitance and inductance according to the smallest detected mismatch.

### SUMMARY OF THE INVENTION

The present invention is a system and a method for on-chip impedance matching using a shunt variable capacitor, a serial load inductance and a control unit that enables tuning of the variable capacitor and detection of a corresponding signal peak (SP). The control unit enables digital setting of the variable capacitor's capacitance value and determining of an optimal capacitance value that corresponds to an optimal SP.

A feature of the present invention is that the impedance matching circuit (NC) uses a shunt variable capacitor to match the impedance, whereas most of the related art circuits use at least one additional variable inductor or a variable resistor to enable the impedance match. Using a single variable capacitor enables the on-chip components of the IMC to occupy a much smaller space of the chip they are placed on.

The present invention allows process variations tolerance—an important feature in on-chip impedance matching, since submicron (nano) ranges of electromagnetic processes introduce more process variations that may be experienced by the circuit's components such as resistors, capacitors and inductors. Typically, capacitors have the widest process variation; therefore a matching technique that uses variable capacitance provides a higher control over the process tolerance.

The present invention further allows a wide range of power matching, as well as linearity and error vector magnitude (EVM) optimization. The linearity is optimized with a purely real load, since the circuit does not require extra current or voltage swing to deliver the power to the load. An extra current or voltage may prematurely clip the signal. For a transmit system, the output performance is limited by linearity, which in turn, sets the EVM. By maximizing the output signal and designing the matching such that maximum signal also supplies the highest output match—no linearity degradation is caused by need extra input signal for the same output power.

### BRIEF DESCRIPTIONS OF THE DRAWINGS

The subject matter regarded as the invention will become more clearly understood in light of the ensuing description of embodiments herein, given by way of example and for purposes of illustrative discussion of the present invention only, with reference to the accompanying drawings, wherein.

FIG. 1 is a schematic illustration of a system for impedance matching via a variable capacitor, according to an embodiment of the present invention; and

FIG. 2 is a schematic illustration of a method for impedance matching via a variable capacitance, according to an embodiment of the present invention.

The Figs. together with the description make apparent to those skilled in the art how the invention may be embodied in practice.

An embodiment is an example or implementation of the inventions. The various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention may also be implemented in a single embodiment.

### DETAILED DESCRIPTIONS OF SOME EMBODIMENTS OF THE INVENTION

The present invention is directed to a system and a method for impedance matching using a variable capacitor 12. An impedance matching circuit IMC matches the impedance of two ports: an output source, for example an amplifier 24 and an input load, for example a resistor 32. The IMC includes a control unit 14 that enables tuning of the variable capacitor 12 to several capacitance values, detection of signal peaks (SP) that are corresponding to the tuned capacitance values, determining a substantially optimal SP and tuning of variable capacitor 12 to a substantially optimal capacitance value that is corresponding to the substantially optimal SP.

While the description below may contain many specifications, these should not be construed as limitations on the scope of the invention, but rather as exemplifications of the preferred embodiments. Those skilled in the art will envision other possible variations that are within its scope, Accordingly, the scope of the invention should be determined not by the embodiment illustrated, but by the appended claims and their legal equivalents.

Reference in the specification to “one embodiment”, “an embodiment”, “some embodiments” or “other embodiments” generally means that a particular feature, structure, or characteristic described in connection with the embodiments is included in at least one embodiments, but not necessarily all embodiments, of the inventions. It is understood that the phraseology and terminology employed herein is not to be construed as limiting and are for descriptive purpose only.

The principles and uses of the teachings of the present invention may be better understood with reference to the accompanying description, figures and examples. It is to be understood that the details set forth herein do not construe a limitation to an application of the invention. Furthermore, it is to be understood that the invention can be carried out or practiced in various ways and that the invention can be implemented in embodiments other than the ones outlined in the description below.

It is to be understood that the terns “including”, “comprising”, “consisting” and grammatical variants thereof do not preclude the addition of one or more components, features, steps, or integers or groups thereof and that the terms are to be construed as specifying components, features, steps or integers. The phrase “consisting essentially of”, and grammatical variants thereof, when used herein is not to be construed as excluding additional components, steps, features, integers or groups thereof but rather that the additional features, integers, steps, components or groups thereof do not materially alter the basic and novel characteristics of the claimed composition, device or method.

If the specification or claims refer to “an additional” element, that does not preclude there being more than one of the additional element. It is to be understood that where the claims or specification refer to “a” or “an” element, such reference is not be construed that there is only one of that element. It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks. The term “method” refers to manners, means, techniques and procedures for accomplishing a given task including, but not limited to, those manners, means, techniques and procedures either known to, or readily developed from known manners, means, techniques and procedures by practitioners of the art to which the invention belongs. The descriptions, examples, methods and materials presented in the claims and the specification are not to be construed as limiting but rather as illustrative only.

Meanings of technical and scientific terms used herein are to be commonly understood as by one of ordinary skill in the art to which the invention belongs, unless otherwise defined. The present invention can be implemented in the testing or practice with methods and materials equivalent or similar to those described herein.

Any publications, including patents, patent applications and articles, referenced or mentioned in this specification are herein incorporated in their entirety into the specification, to the same extent as if each individual publication was specifically and individually indicated to be incorporated herein. In addition, citation or identification of any reference in the description of some embodiments of the invention shall not be construed as an admission that such reference is available as prior art to the present invention.

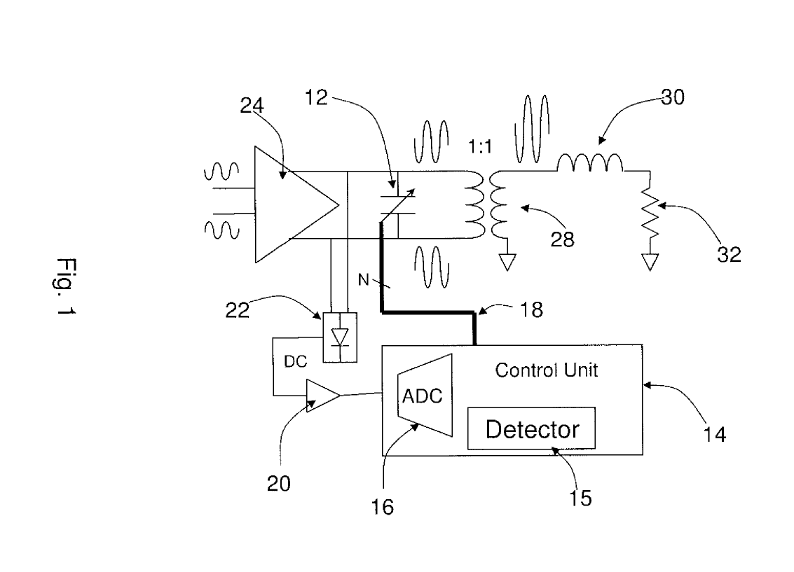

FIG. 1 schematically illustrates a system for impedance matching between an output source and an input load, according to some embodiments of the present invention. Said system includes an impedance matching circuit (IMC), wherein IMC comprises:
a discrete shunt variable capacitor 12;
a control unit 14 that includes a peak detector 15 and an analog to digital converter (ADC) 16;
a network on-chip link 18;
an alternating current to direct current (AD) rectifier 22 that comprises at least one diode;
a direct current (DC) amplifier 20 that is connected to rectifier 22.

The output source may transmit a test signal (TS) via an amplifier 24. IMC is connected to the input load of a load inductance unit 28, an inductor 30 and a resistor 32. The impedance matching may be carried out through an external TS or a signal generated, for example, by a local oscillator (LO) leakage, which can be generated without the need of an external source.

According to an embodiment of the present invention, as illustrated in FIG. 1, shunt variable capacitor 12 is connected to the IMC in a parallel connection, where load inductance unit 28 is connected to the IMC in a serial connection, where resistor 32 is the real load of the input load.

According to an embodiment of the present invention, as illustrated in FIG. 1 and the above description, variable capacitor 12 is digitally controlled by control unit 14. Control unit 14 enables tuning of variable capacitor 12 to controlled and known capacitance values.

Rectifier 22 receives alternative current AC and converts it into a direct current DC, since the test signal is an AC signal. According to embodiments of the present invention, conversion to a DC is used for peak measuring; peak detector 15 measures only positive or absolute values of amplitude. Rectifier 22 converts all negative amplitude peaks into positive and enables measuring of amplitude absolute peak.

Peak detector 15 may enable measuring of the signal peaks (SP) resulting from the corresponding capacitance values of variable capacitor 12 that are tuned through control unit 14.

According to an embodiment of the present invention, as illustrated in FIG. 1, control unit 14 tunes variable capacitor 12 to a known capacitance value. Peak detector 15 detects the SP that is corresponding to the specific, tuned capacitance value. Control unit 14 repeats this process over for several predefined different values of capacitance. Control unit 14 enables saving and processing of predefined capacitance values data and SP data extracted from peak detector 15. Control unit 14 may determine a substantially optimal SP through a fitting algorithm, carried out in control unit 14 and enables tuning variable capacitor 12 to a substantially optimal capacitance value, where the optimal capacitance value is corresponding to the optimal SP.

According to embodiments of the present invention, the fitting algorithm may be any algorithm that enables determining of a substantially optimal SP. For example, the fitting algorithm may be a polynomial approximation fit of a predefined polynomial degree for calculating the capacitance value that gives the highest SP. The highest SP is the substantially optimal SP and the corresponding capacitance value is the substantially optimal capacitance value. Control unit 14 may then tune variable capacitor 12 to the closest available capacitance value there is to that of the optimal capacitance value found by the fitting algorithm.

For example, variable capacitor 12 may have three discrete capacitance values: 1 microfarad, 2 microfarads and 3 microfarads. The fitting algorithm determines the highest SP to be at 1.75 microfarads. Since, in this example, variable capacitor 12 cannot be tuned in a non-integer number, control unit 14 may round the calculated value to 2 microfarads.

According to embodiments of the present invention, the SP detection may be carried out only through part of the capacitance values available by variable capacitor 12. For example, variable capacitor 12 that has a tuning range between 1 microfarad to 10 microfarads in intervals of 1 microfarad. Detector 15 and control unit 14 only check SPs of three predefined values: 4, 5 and 6 microfarads. The fitting algorithm may determine an optimal SP corresponding to 7 microfarads, through extrapolating the three detected corresponding SPs. The corresponding optimal capacitance value is within variable capacitor's 12 range but not one of the tested capacitances.

According to embodiments of the present invention, control unit 14 may determine a substantially optimal SP through comparing all detected SPs and choosing of the highest SP. Control unit 14 may then tune variable capacitor 12 to a substantially optimal capacitance value, corresponding to the optimal SP.

According to embodiments of the present invention, ADC 16 may be external to the system. According to other embodiments of the present invention, ADC 16 may be internal—as an on-chip component.

According to embodiments of the present invention, detector 15 may be external to the system. According to other embodiments of the present invention, detector 15 may be included as part of control unit 14.

According to embodiments of the present invention, variable capacitor 12 may be a discrete and digitally controlled variable capacitor 12 such as a capacitors-bank, an analog variable capacitor 12 or any other method and devices known in the art that enable tuning of a capacitor to various capacitance values.

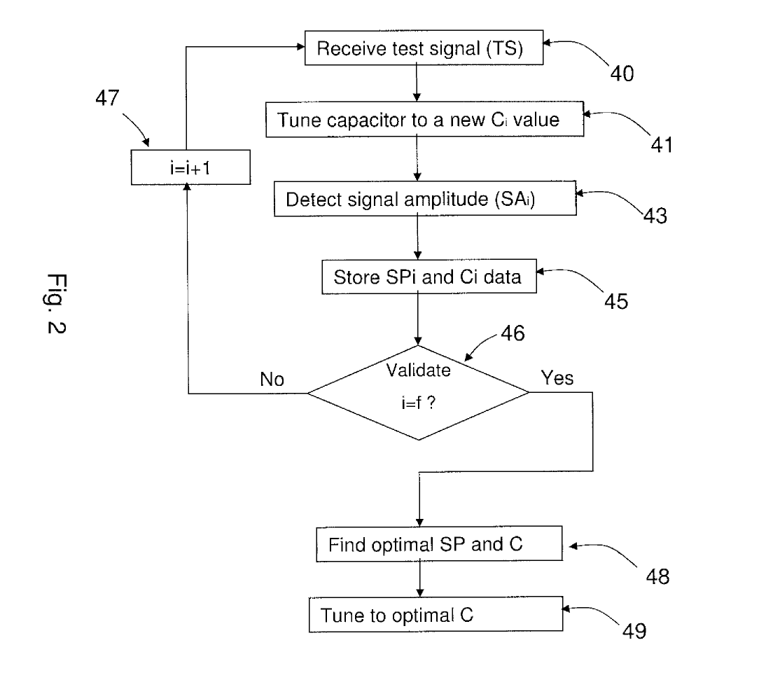

FIG. 2 schematically illustrates a method for impedance matching, according to some embodiments of the present invention said method comprises the steps of:
receiving test signal (TS) 40, wherein said TS is constant and substantially equal through all following steps and iterations;
tuning capacitor 41: variable capacitor 12 is tuned to a new capacitance value Cᵢ, wherein “i” indicates iteration number where the total number of iterations is final and predetermined. A first capacitance value C₁ is predetermined, according to theoretical assessment and calculation;
detecting signal peak (SP) 43: detector 15 detects the signal peak SP corresponding to Ci;
storing data 45: control unit 14 stores all capacitance values and their corresponding signal peaks;
validating 46 final iteration: where “f” is the predefined number of iterations; if “i” does not equal “f” iterations are not final and the process repeats iterating from step 40, by setting new values of capacitance and detecting corresponding SP;
moving to the next iteration 47;
determining the optimal SP and C 48: if iterations are final, control unit 14 determines the optimal SP;
tuning to optimal C 49: control unit 14 tunes variable capacitor 12 to an available capacitance value that is closest to the optimal capacitance value.
   The highest SP indicates the substantially best impedance between the IMC and input load, since the highest SP indicates the lowest return loss.

According to embodiments of the present invention, the step of determining the optimal SP 48 may be carried out through a fitting algorithm. The fitting algorithm enables mathematical calculation of the optimal SP. The highest SP found by the fitting algorithm is deemed to be the substantially optimal SP and the corresponding capacitance value is deemed to be the optimal capacitance value.

According to embodiments of the present invention, the fitting algorithm may be any algorithm that enables calculation and determining of an optimal SP, wherein an optimal SP definition is predetermined by the system. For example, polynomial approximation and peak search defining the optimal SP as the polynomial peak calculated by extrapolation over SPi and Ci values; determining the highest SPi of all detected SPs through comparison and defining of an optimal SP as the highest detected SPi, etc.

According to other embodiments of the present invention, and according to embodiments of the step of determining the optimal SP 48, optimal SP may be determined as a comparison between all SPs that were detected by peak detector is and choosing of the highest detected SP as the optimal SP. According to these embodiments, the optimal capacitance value corresponds to the capacitance value that resulted in the highest SP.

According to embodiments of the present invention, tuning to optimal capacitance value, as indicated in step 49, depends on the predetermined definition of an optimal SP: if optimal SP is defined by the system as the highest detected SPi, then optimal capacitance value may be the capacitance value Ci corresponding to the optimal SPi. If optimal SP is defined as the peak of a polynomial approximation, for example, then the optimal capacitance value nay be a capacitance value available by variable capacitor 12 that has the closest value to the theoretical capacitance value that corresponds to the optimal SP.

According to embodiments of the present invention, the predefined number of iterations “i” may be smaller than the number of capacitance values that are available by variable capacitor 12.

While the invention has been described with respect to a limited number of embodiments, these should not be construed as limitations on the scope of the invention, but rather as exemplifications of some of the preferred embodiments. Those skilled in the art will envision other possible variations, modifications, and applications that are also within the scope of the invention. Accordingly, the scope of the invention should not he limited by what has thus far been described, but by the appended claims and their legal equivalents.

What is claimed is:

1. A system for on-chip impedance matching of at least two ports, wherein one port is an output source and a second port is an input load, said system includes an on-chip integrated impedance matching circuit (IMC) that comprises:
at least one variable capacitor;
a control unit for tuning the variable capacitor, and for saving, receiving and transmitting of signals and processing of signals;
at least one peak detector for detecting of signal peaks;
wherein the control unit determines a substantially optimal signal peak and performs tuning of the variable capacitor to a substantially optimal capacitance that corresponds to the optimal signal peak.

2. The system of claim 1 further comprising at least one network communication on-chip link that connects the control unit with the variable capacitor and enables the tuning of the variable capacitor

3. The system of claim 1 further comprising at least one rectifier for converting of an AC to a DC.

4. The system of claim 1, wherein the control unit further enables converting of analog signals to digital signals through an AD converter.

5. The system of claim 1, wherein the control unit saves capacitance values that have been tuned by the control unit, as well as signal peaks that correspond to the said capacitance values.

6. The system of claim 1, wherein determining of the substantially optimal signal peak is carried out through a fitting algorithm, wherein said fitting is carried out through a mathematical calculation of the signal peaks and their corresponding capacitance values that have been saved by the control unit

7. The system of claim 1, wherein determining of the substantially optimal signal peak is carried out through comparing all signal peaks that have been saved by the control unit and choosing the highest signal peak as the optimal signal peak.

8. The system of claim 1, wherein the variable capacitor comprises a discrete shunt variable capacitor that is integrated into the IMC through a parallel circuit connection

9. The system of claim 1, wherein the variable capacitor comprises an analog variable capacitor.

10. The system of claim 1 wherein the input load is connected through at least one inductor and at least one resistor, wherein said resistor is the real load.

11. The system of claim 10, wherein the inductor is connected in series to the input load.

12. The system of claim 1, wherein the control unit tunes the variable capacitor to at least part of the predefined capacitance values enabled by the variable capacitor.

13. A method for on-chip impedance matching of at least two ports, wherein one port is an output source and a second port is an input load, wherein said method is implemented with an impedance matching circuit (IMC) that comprises a variable capacitor, a control unit and at least one peak detector, said method comprises the steps of:
receiving a signal;
tuning the variable capacitor, wherein the variable capacitor is tuned to a new capacitance value;
detecting a signal peak (SP), wherein the peak detector that is connected to the control unit detects the SP that results from the corresponding tuned capacitance value;
storing data, wherein the control unit stores capacitance values and their corresponding signal peaks;
determining an optimal SP, wherein control unit determines a substantially optimal SP and a corresponding optimal capacitance value;
tuning the variable capacitor to the substantially optimal capacitance value;
wherein the substantially optimal capacitance value is a capacitance value available by the variable capacitor.

14. The method of claim 13, wherein the IMC is connected to an output source and an input load.

15. The method of claim 13, wherein receiving of a signal is enabled through an amplifier that is connected to the output source.

16. The method of claim 13, wherein the control unit enables tuning of the variable capacitor, saving of signal peaks, receiving and transmitting of signals and processing of signals.

17. The method of claim 13, wherein the control unit enables tuning the variable capacitor to at least some of the capacitance values that are available by the variable capacitor.

18. The method of claim 13, wherein the variable capacitor comprises a digitally controlled discrete variable capacitor.

19. The method of claim 13, wherein the variable capacitor comprises an analog variable capacitor.

20. The method of claim 13, wherein the step of determining of the substantially optimal signal peak is carried out through a fitting algorithm, wherein said fitting is carried out through a mathematical calculation of the signal peaks and their corresponding capacitance values that have been saved by the control unit.

21. The method of claim 13, wherein determining of the substantially optimal signal peak is carried out through comparing all signal peaks that have been saved by the control unit and choosing the highest saved signal peak.
